(19) United States
(12) Patent Application Publication
(10) Pub. No.: US 2009/0003098 A1
(43) Pub. Date: Jan. 1, 2009

(54) Method for Hiding Defective Memory Cells and Semiconductor Memories

(76) Inventors: Benedikt Hoess, Petershausen (DE); Werner Leeb, Starnberg (DE)

Correspondence Address: SLATER & MATSIL, L.L.P., 17950 PRESTON ROAD, SUITE 1000, DALLAS, TX, 75252, US

(21) Appl. No.: 12/147,323

(22) Filed: Jun. 26, 2008

(30) Foreign Application Priority Data
Jun. 26, 2007 (DE) 10 2007 029 371.4

(51) Int. Cl. G11C 29/04; G11C 29/18

(52) U.S. Cl. 365/200

(57) ABSTRACT

A method for hiding defective memory cells in a semiconductor memory having a plurality of memory cells coupled with word lines for controlling is suggested. In the method, at least one word line is determined, where one control signal selects the at least one defective memory cell. For hiding the at least one defective memory cell, a signal inverted with regard to the selection signal is applied to the at least one determined word line during addressing of the plurality of memory cells.

This application claims priority to German Patent Application 10 2007 029 371.4, which was filed Jun. 26, 2007 and is incorporated herein by reference.

### TECHNICAL FIELD

The present invention relates generally to semiconductor memories and, in particular embodiments, to a method for hiding defective memory cells in a semiconductor memory.

### BACKGROUND

Nowadays, semiconductor memories are used in a plurality of applications. They serve, for example, as main memory in a computer system, but are also used as memories for graphics cards, accordingly called graphic memories. Semiconductor memories include a plurality of individually addressable memory cells, in each of which one logic datum can be stored.

During production of the semiconductor memory, failures of individual memory cells can occur due to production. This can show, for example, in a short circuit between a memory capacitor of the memory cell with the surrounding semiconductor substrate. Thereby, the memory capacitor might not store the load stored therein for a sufficiently long time. Further, individual address or word lines, respectively, can include defects, which, for example, cause a large resistance. During a test phase performed during production the defects are detected and, if possible, corrected by redundant circuits.

But there is still the need to provide a method for hiding defective memory cells.

### BRIEF DESCRIPTION OF THE DRAWINGS

Embodiments of the present invention will be detailed subsequently referring to the appended drawings, in which

FIG. 1 is a schematic illustration of a semiconductor memory with substantial elements;

FIG. 2 is a schematic illustration of an address decoder for illustrating the method for hiding defective memory cells;

FIG. 3 is a portion of a memory cell field with defective memory cells;

FIG. 4 is a diagram for explaining an embodiment of the method for hiding defective memory cells; and

FIGS. 5 and 6 are embodiments of the method for hiding defective memory cells.

### DETAILED DESCRIPTION OF ILLUSTRATIVE EMBODIMENTS

In the following description, further aspects and embodiments of the present invention are summarized. Additionally, reference is made to the appended drawings, which form part of the description and which show by illustration how the invention can be embodied in practice. The embodiments of the drawings represent a summary to allow better understanding for one or several aspects of the present invention. This summary is not a complete overview of the invention and does not intend to limit the features or key elements of the invention to a certain embodiment. Particularly, they merely serve to provide an overview. The measures and numbers disclosed in these embodiments are not limiting, but serve merely as examples to improve the understanding of the invention and the different aspects. The different elements, aspects and features disclosed in the embodiments can be combined in different ways by a person skilled in the art to obtain one or several advantages of the invention. It is to be understood that other embodiments can be used and that structural or logical changes can be performed without leaving the central idea of the present invention. The elements in the drawings are not necessarily true to scale. The same reference numbers relate to corresponding similar parts.

When producing semiconductor memories, individual or several memory cells can fail. Individual word or bit lines coupled to the memory cells can also be defective.

Thus, in part, memory cells as well as leads and further circuits are tested for their functionality after individual production steps. Then, redundant memory cells can, for example, replace memory cells classified as defective. In detail, this is performed by so-called fuse or bonding production steps, where defective memory cells are bypassed and replaced by redundant memory cells. For this reason, additional memory cells, word lines and bit lines are provided when producing a semiconductor memory, which can then replace the defective elements if needed. In this manner, the desired overall memory size can be obtained again.

However, the number of defects and the specific arrangement of defects within the memory area of a semiconductor memory, respectively, can render correction or compensation by redundant memory cells impossible. Correspondingly, defective memory cells would still be present in the semiconductor memory, even after such fuse or bonding steps. Such semiconductor memories with additional, so far uncorrectable defective memory cells are then discarded.

In order to be able to continue using the discarded semiconductor memories, the invention suggests hiding the same by a specific method and thus providing the possibility of continuing using functioning and active memory cells.

In this method, one or several address lines are located, which each have the same level in addressing the defective memory cells. These defective memory cells can then be masked by applying an inverted level to the address line after initialization. Thereby, the defective memory cells are not addressed, but addressing is limited to the functioning memory cells of the semiconductor memory. This has the effect that the memory chip has less memory capacity. If, for example, an address line is masked using this method, the memory has now half the memory capacity (so-called half good or half capacity memories). Thus, for a respective application in a computer system, twice the number of semiconductor memories is required for the same memory capacity.

By the inventive method, it is possible to program individual register bits via external logic during initialization of internal memory registers. Also, programming of the internal memory register can take place, for example, via the address lines. Additionally, masking of bank addresses can be performed, if, for example, the defects occur mainly in a memory bank.

In another embodiment, defective memory cells can be masked in a memory area by limiting the semiconductor memory in a computer system to a part of the available overall address space. This can, for example, be performed by a respective BIOS setting in the computer system. The method can be performed particularly when address lines are used both for row and column addressing in volatile memories, which means the same are multiplexed.

As long as the high-order address lines in volatile memories are only used for row addressing, these address lines can be particularly suitable for masking.

It is also possible to store information about defective memory cells, for example, the number of word lines coupled to the same, in a specific memory area, for example, in a register. Based on this information, the semiconductor memory can mask the defective memory cells during operation if needed.

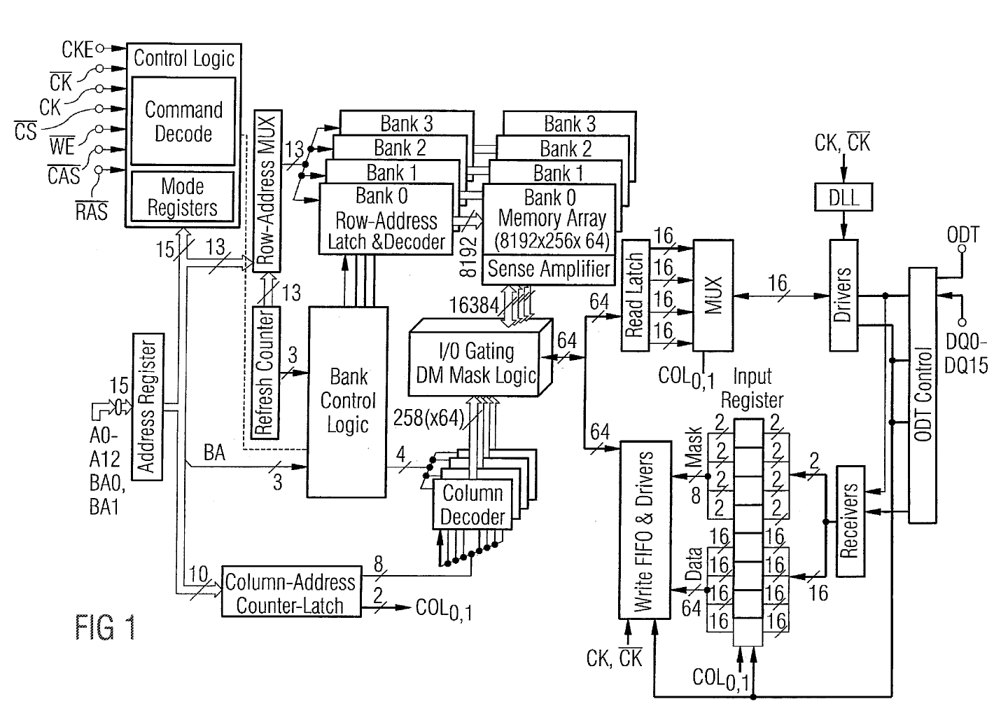

FIG. 1 shows a schematic illustration of a semiconductor memory for illustrating the method for hiding defective memory cells. The semiconductor memory comprises a memory area with a sense amplifier coupled to the same. The memory area “memory array” , where the data are stored in memory cells, is divided into individual memory banks bank 0 to bank 3, which are addressed by a corresponding selection signal. The signal is also referred to as the “bank address” and provided by a logic circuit “bank control logic”. This circuit evaluates a 3-bit word, which is supplied to the semiconductor memory on the input side and includes information about the memory bank. In the embodiment the respective address decoder “row address decoder” coupled to the corresponding memory bank is addressed using the logic circuit “bank control logic”. The number of memory banks results in b=2ⁿ−1. Depending on the control word on the bank address line BA, the circuit “bank control logic” generates the selection signal and outputs the same to the respective row decoder “row address latch & decoder” as well as a column decoder. The same then address the selected bank and, if applicable, control the sense amplifier for the respective memory area.

The individual memory areas in the different banks bank 0 to bank 3 comprise a plurality of memory cells arranged in rows and columns. Each of them includes a control transistor whose control terminal is coupled to one of the word lines. A memory capacitor, which can, for example, be implemented as a deep trench capacitor, is coupled to the control transistor.

The row decoders “row address latch & decoder” of the semiconductor memory are further implemented to convert an address word coming from an address bus “A0 . . . A12” into a plurality of addressing signals for the respective memory bank. For this purpose, the individual row decoders “row address latch & decoder” are coupled to a multiplexer “row address MUX” on the input side. The same is coupled to the input terminal of the address bus via an address register. Further, the row decoder “row address latch & decoder” also includes circuits for refreshing the memory cells of the memory area.

In this embodiment the address bus “A0 . . . A12” comprises a width of 13 bits. An address word on the address bus is first supplied to the address register, which also receives the selection word BA0, BA1 for the respective memory bank. The address word is applied to the multiplexer “row address MUX” and supplied to a control logic, which is also responsible for masking defective memory cells in the semiconductor memory. The control logic includes a register where the number of word lines, which are coupled to defective memory cells, is stored. Additionally, the control logic controls significant functions like a refresh process and provides for the correct control of the individual elements during a write or read process.

For this purpose, the control logic is coupled to the terminals for the signals CKE, CS, WE, CAS, RAS as well as for the clock signal CK. Also, the signals are supplied to the same on the bank address line “B0 . . . B1”. The control logic controls the further circuits, such as row and column decoders.

In this embodiment, not only the row address is transmitted to the row decoder “row address latch & decoder” via the address bus “A0 . . . A12”, but also a column address to the column decoder. In the present embodiment, the column address comprises a length of 10 bits and uses the address lines “A0” to “A9” of the address bus.

Sharing an address bus for transmitting the row or column address, respectively, is referred to as multiplexing. The column address on the low-order address lines “A0” to “A9” of the address bus is supplied to a latch “column address counter/latch” which forwards an 8-bit word to one of the column decoders. One of the column decoders is determined from the selection word BA via the control logic “bank control logic”, and generates the respective control signals for read and write access for controlling the sense amplifier and opening the bit lines in the memory areas. In this embodiment, one of the 256 columns is selected from the column address by the column decoder. For determining the row address, one signal is used on all address lines of the address bus “A0 . . . A12”.

In this embodiment, during a read or write process, 64 memory cells in one of the banks are opened by controlling the row and column decoder, and the read-out signals are amplified in sense amplifiers. The 64 bits are supplied to an output circuit via a circuit “I/O gating DM mask logic”. The same includes receiver and driver circuits as well as latches for buffering the data word to be written or read.

The 64-bit wide data word read from the memory is provided at the terminal via a data bus “DQ0 . . . DQ15”, and a data word supplied to the terminal is written into the addressed and opened memory cells, respectively.

During the production of the semiconductor memory, irreversible and uncorrectable defects can occur in the memory area of the individual memory cells. Other areas of the memory area, such as word or bit lines can also be damaged or defective. In subsequent test phases, the defective memory cells are identified and, if necessary, replaced by redundant memory cells. Further defects are masked with the suggested method by first looking for defective memory cells or areas, which have the respective same level on one of the address lines during addressing. For masking, the address line found is provided with a fixed level, so that the same does not address defective memory cells during addressing. Thereby, the defective memory cells are ignored, and as a result only the functioning memory cells are addressed, written into as well as read from.

Masking can be performed with the help of the control logic. The same includes a register where the “numbers” of the word lines with defective memory cells are stored. If an address word is supplied, which controls one of these word lines, the control logic masks one bit of the address word so that the word line with the defective memory cells is no longer controlled.

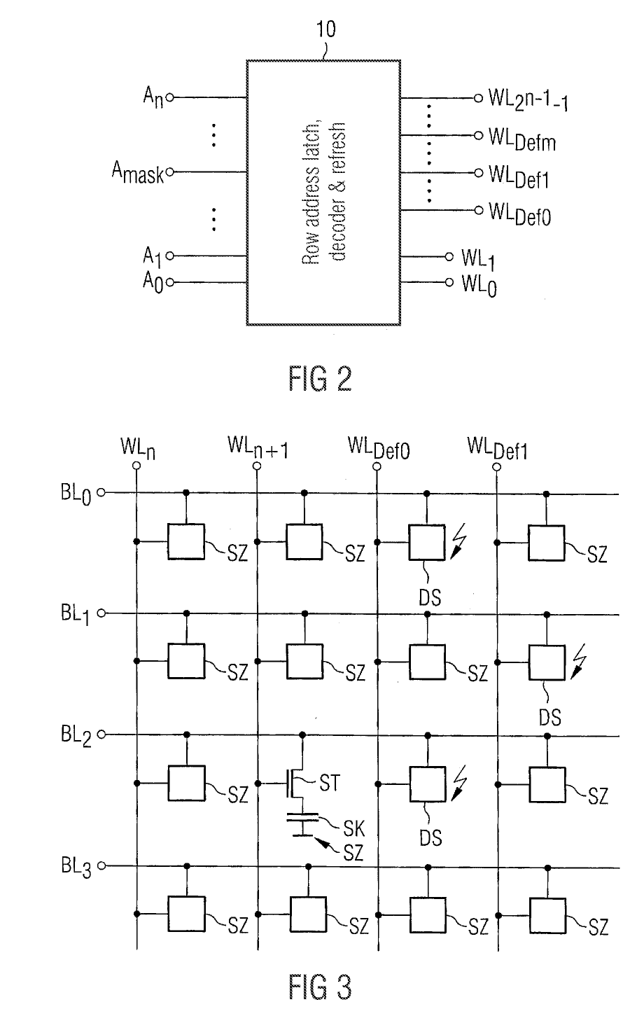

FIG. 2 shows a row address decoder as well as a refresh circuit for illustrating the suggested principle. An address word of the width of n is supplied to the row decoder 10. The individual bits of the address word are distributed on the address lines A0 to An and applied to the row decoder 10. In the illustrated embodiment, for avoiding addressing of defective memory cells, one bit of this address word is provided with a fixed value on one of the address lines Aₘₐₛₖ and is thus masked. In the row decoder 10, signals are generated from the address word with the masked bit on the word lines for addressing the memory cells. Part of the word lines is coupled to defective memory cells.

By masking the address bit on the address line Aₘₐₛₖ, the respective word lines WL_{Def0} to WL_{Defm} are provided with the above-mentioned masking signals, while the defective memory cells coupled therewith are not addressed. Reading or writing only takes place from the functioning memory cells but not from the defective memory cells coupled to the word lines WL_{Def0} to WL_{Defm} so that no memory fault can occur.

FIG. 3 shows a schematical illustration of a section of a memory area with defective memory cells DS. The memory cells SZ, DS are coupled between intersections of word lines WLₙ, WLₙ₊₁ to WL_{Def0}, WL_{Def1} and bit lines BL0 to BL3. The memory cells coupled with these word lines are selected by a signal on the corresponding word line, for example, word line WLₙ₊₁. Depending on the charge stored therein, they generate a signal level corresponding to a logical “0” or a logical “1” on the bit line BL0 to BL3, which is also coupled therewith.

Therefore, every memory cell SZ, DS includes a control transistor ST, whose gate terminal is coupled to the corresponding word line. One terminal of the control transistor is coupled to the bit line, the second to the memory capacitor SK. The same can, for example, be implemented as “deep trench” capacitor.

As illustrated in the embodiment of FIG. 3, some of the memory cells DS of the memory area are defective. Partly, the defective memory cells DS are coupled with their control terminals to the same word line WL_{Def0} but also to an additional word line WL_{Def1}. In order to avoid a memory fault during a read and write process, respectively, the word lines WL_{Def0} and WL_{Def1} are not considered during addressing or the same are masked. For masking, the word lines WL_{Def0} and WL_{Def1} are always provided with a constant level, which does not address the gate of the control transistor. Thus, merely the functioning memory cells SZ in the word lines WLₙ and WLₙ₊₁ are addressed.

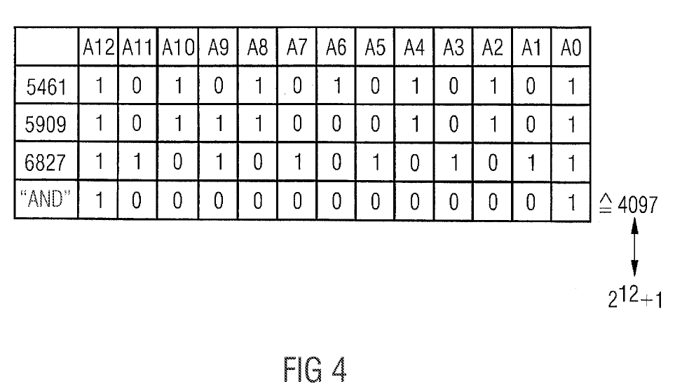

FIG. 4 shows a diagram with different defective memory cells in word lines for illustrating a determination of the address line to be masked. In the present example, 13 address lines with A0 to A12 are provided. The corresponding word lines run from WL0 to WL8191, which corresponds to the number 2¹³. Defective memory cells are in the word lines 5461, 5909 as well as 6827. The word line 5461 is addressed by the address word 1010101010101 illustrated in the diagram according to FIG. 4. The further word lines are encoded by the correspondingly illustrated address words. For determining the address lines to be masked, a logical AND operation is performed with the word lines marked as defective. This results in the bit sequence located in the fourth row of the second column, which corresponds to the decimal number 4097. For determining the associated address line A, the natural logarithm to the base of two is formed from this number. This results approximately in the number 12. Correspondingly, the address line A12 is masked in order to hide the defective memory cells in the word lines.

Thus, for the method the memory cells addressed by the individual word lines are tested for defects. The word lines detected in this way are coupled to each other by a logical AND operation and the result of this operation is processed further. For example, the address line to be masked can be determined from the used algorithm of the row decoder by determining the corresponding address line from the result of the logic operation and masking the bit on the same.

Thus, for example, the following mapping regulation applies:

If (def0 ̂ def1 ̂ . . . ̂ defm)≠0

then mask=└lb(def0 ̂ def1 ̂ . . . ̂ defm)┘ and Aₘₐₛₖ=0

else

if ( d̅e̅f̅0̅ ̂ d̅e̅f̅1̅ \hat{0} . . . ̂ d̅e̅f̅m̅)≠0

then mask=└lb( d̅e̅f̅0̅ ̂ d̅e̅f̅1̅ ̂ . . . ̂ d̅e̅f̅m̅)┘ and Aₘₐₛₖ=1

else

no match found.

Here, ̂ is the logical AND operator, lb the logarithm of 2 for finding the corresponding address line. For masking, merely the integer portion is used, which indicates the most significant bit of the address word to be masked. This is indicated by the Gaussian bracket └ ┘. Aₘₐₛₖ=0 means that a lower level is to be applied for masking. Thus, the corresponding bit is pulled to a lower level during addressing or a transfer of an address word to the row decoder, respectively.

FIG. 5 shows an embodiment of the method for masking defective memory cells in a memory. In a first step S1, when applying an address word for addressing the row and thus controlling the word line, a level is applied to at least one of the address lines, which is inverted with regard to the address signal on this line. Thus, not the originally applied address word is processed in the row decoder, but one that differs by at least one bit. Consequently, during conversion of the altered address word in step S2, no control signals are generated on those word lines that are coupled to defective memory cells. The memory cells are controlled in step S3.

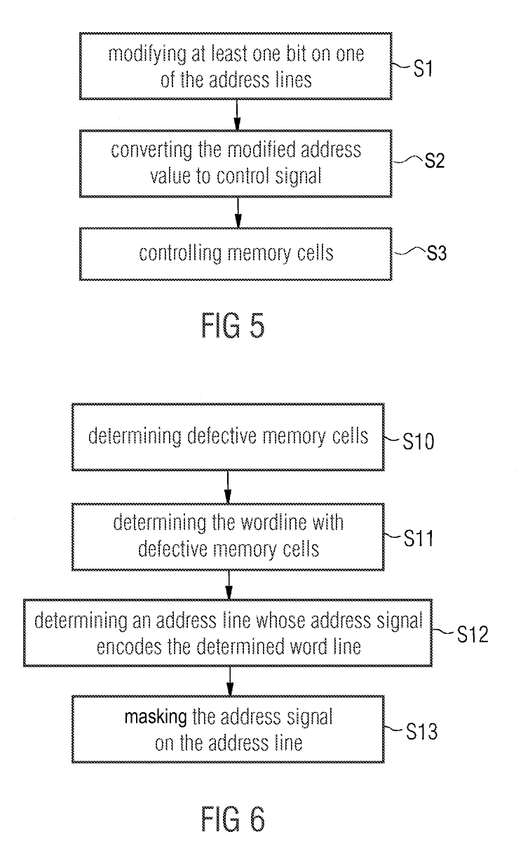

FIG. 6 shows a further embodiment of the method for determining and masking defective memory cells. In this embodiment, the defective memory cells are determined in a first step S10. This can be performed, for example, by writing known data into the individual memory cells and subsequently reading the same out again. The read data are then compared to the original data. When the structure and layout of the semiconductor memory is known, the memory cell can be determined when there is no match. After a more detailed test, the memory cell is marked as defective.

After such a test phase, conventional repair measures can be taken, such as, for example, replacing the defective memory cells by redundant cells. It is also convenient to combine conventional correction and repair measures with the suggested methods to increase the overall yield of memories.

In a subsequent step S11, the associated word lines are determined, to which the defective memory cells are coupled. As long as the memory cells are coupled to different word lines, step S12 tries to find an address line encoding all the word lines detected in the previous step. This can be performed, for example, by the above-mentioned method. As long as there is such a common address line, the address signal can be masked on this address line (step S13). Thus, the level present on the determined address line is inverted in an address word, which would possibly control these word lines. Alternatively, a constant level is supplied to the address line.

If, for example, the word lines with the defective memory cells are addressed by the address line with a high level, logic “1”, this address line is constantly set on a lower level, logic 0, for masking.

With the inventive method, the yield of semiconductor memories with individual defective memory cells can be improved. Thus, for example, memory devices whose defective memory cells cannot be fully corrected by conventional fuse and/or bond repair can still be used. Additionally, the circuit complexity of such repair methods can be easily reduced when the semiconductor memory can be limited to the functioning memory cells in its address space by appropriate masking of defective word lines.

While this invention has been described in terms of several advantageous embodiments, there are alterations, permutations, and equivalents which fall within the scope of this invention. It should also be noted that there are many alternative ways of implementing the methods and compositions of the present invention. It is therefore intended that the following appended claims be interpreted as including all such alterations, permutations, and equivalents as fall within the true spirit and scope of the present invention.

What is claimed is:

1. A method of hiding defective memory cells in a semiconductor memory comprising a plurality of memory cells coupled with word lines for controlling, the method comprising:
determining at least one word line on which a control signal controls at least one defective memory cell; and
applying a signal inverted with regard to the control signal to the at least one determined word line for hiding the at least one defective memory cell while addressing the plurality of memory cells.

2. The method according to claim 1, further comprising providing an address word comprising a plurality of bits and converting the address word into the control signal, wherein at least one bit of the address word is masked for hiding the at least one defective memory cell.

3. The method according to claim 2, wherein every bit of the address word is transmitted on an address line, wherein one of the address lines is provided with a lower level for hiding the at least one defective memory cell.

4. The method according to claim 1, wherein several defective memory cells are controlled by different address words each comprising a number of bits, and those bits of the address words having the same control level are masked for hiding the defective memory cells.

5. The method according to claim 4, wherein individual bits of the address words are linked by a logic operation for hiding the defective memory cells.

6. The method according to claim 1, further comprising determining an address word coding at least one word line after determining the at least one word line.

7. A method of hiding defective memory cells in a semiconductor memory comprising a plurality of memory cells organized in at least two memory banks, and wherein at least one memory cell in one of the at least two memory banks is defective, the method comprising applying a signal inverted with regard to a selection signal for hiding the defective memory cells during a selection process of the one memory bank.

8. The method according to claim 7, wherein a bank addressing word with a plurality of bits is provided for the selection of one of the memory banks, and at least one bit of the bank addressing word is masked for hiding at least one defective memory cell.

9. A method of hiding defective memory cells in a semiconductor memory, the method comprising:
providing a semiconductor memory comprising a plurality of memory cells arranged at intersections of word and bit lines, wherein the memory cells can be controlled by control signals on the word lines, the semiconductor memory comprising at least one defective memory cell coupled to a first word line;
providing an address word comprising a plurality of bits for selecting a first number of memory cells to the semiconductor memory;
supplying a masking signal to at least one bit of the address word, the masking signal having a logic value that is inverted with regard to a logic value of the at least one bit; and
decoding the address word with the masked signal and generating the control signal on the word line based on the address word.

10. The method according to claim 9, wherein the semiconductor memory comprises a plurality of address lines, wherein every address line carries one bit of the address word, and at least one address line is provided with the masking signal for masking.

11. The method according to claim 9, wherein the address word is used for selecting one bank of the semiconductor memory from at least two banks.

12. The method according to claim 9, further comprising storing an identification of the first word line, and testing an address word supplied to the semiconductor memory as to whether the same controls the first word line.

13. The method according to claim 9, further comprising storing an address area with defective memory cells or an address of a defective memory cell in a register and testing an address word supplied to the semiconductor memory as to whether the same falls into the same stored address area or comprises the stored address.

14. The method according to claim 9, wherein the first word line is provided with a level having an inverted level with regard to the control signal for controlling the at least one defective memory cell.

15. A semiconductor memory comprising
a memory area wherein a plurality of addressable memory cells are arranged, the memory cells being coupled to word lines, at least one addressable memory cell being defective,
a row decoder coupled to the word lines for controlling one of the word lines in response to an address word comprising a number of bits; and
a control unit implemented for changing at least one bit of the address word, so that the row decoder with the changed address word controls word lines with functioning memory cells.

16. The semiconductor memory according to claim 15, wherein the control unit is arranged outside the semiconductor memory.

17. The semiconductor memory according to claim 15, wherein the control unit is part of a BIOS of a computer system or computer system component.

18. The semiconductor memory according to claim 17, wherein the control unit is part of a graphics card.

19. The semiconductor memory according to claim 15, wherein the control unit comprises a memory in which information about word lines having defective memory cells coupled thereto is stored.

20. The semiconductor memory according to claim 15, wherein the control unit comprises a memory in which information about addresses or address areas addressing defective memory cells is stored.
